(19) United States
(12) Patent Application Publication
(10) Pub. No.: US 2025/0105170 A1
(43) Pub. Date: Mar. 27, 2025

(54) SEMICONDUCTOR PACKAGE INCLUDING STRESS-REDUCTION CHAMFERS AND METHODS FOR FORMING THE SAME

(71) Applicant: Taiwan Semiconductor Manufacturing Company Limited, Hsinchu (TW)

(72) Inventors: Tsung-Yen Lee, Hemei Township (TW); Ming-Chih Yew, Hsinchu City (TW); Chin-Hua Wang, New Taipei City (TW); Shin-Puu Jeng, Po-Shan Village (TW)

(21) Appl. No.: 18/475,292

(22) Filed: Sep. 27, 2023

(51) Int. Cl. H01L 23/00; H01L 21/304; H01L 21/48; H01L 21/56; H01L 23/04; H01L 23/31; H01L 25/00; H01L 25/065

(52) U.S. Cl. CPC H01L 23/562; H01L 21/3043; H01L 21/4853; H01L 21/56; H01L 23/04; H01L 23/3128; H01L 24/08; H01L 24/80; H01L 25/0655; H01L 25/50; H01L 2224/08225; H01L 2224/80895; H01L 2224/80896

(57) ABSTRACT

A semiconductor package includes: a package substrate including a horizontal top surface; an interposer bonded to the top surface of the package substrate; a semiconductor die bonded to a top surface of the interposer, the semiconductor die including a bottom surface that faces the top surface of the interposer, and chamfers formed in corners of the bottom surface of the semiconductor die; and a molding layer surrounding the semiconductor die and filling the chamfers.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area.

In addition to smaller electronic components, improvements to the packaging of components seek to provide smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these 3D devices (e.g., 3DIC, SoC, SoIC) are prepared by placing chips over chips on a semiconductor wafer level. These three-dimensional devices provide improved integration density and other advantages, such as faster speeds and higher bandwidth, because of the decreased length of interconnects between the stacked chips. However, there are many challenges related to three-dimensional devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a semiconductor die 100, according to various embodiments of the present disclosure.

FIG. 2A is a simplified top view of a semiconductor package 200, according to various embodiments of the present disclosure.

FIG. 2B is a vertical cross-sectional view taken along line A-A′ of FIG. 2A.

FIG. 2C is a vertical cross-sectional view taken along line B-B′ of FIG. 2A.

FIGS. 3A-3E are partially transparent enlarged top views of a chamfered region R1 of a semiconductor die of FIG. 2A, illustrating various embodiments that may be included in chamfers of FIG. 2C, according to various embodiments of the present disclosure.

FIG. 4 is a vertical cross-sectional view of an alternative chamfer that may be included in the semiconductor dies of FIGS. 2A-2C, according to various embodiments of the present disclosure.

FIG. 5 is a flow diagram showing a method of forming a package substrate, according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A semiconductor package may include multiple semiconductor dies arranged on a package substrate. During testing and/or assembly of a semiconductor package, the semiconductor package may be subjected to thermal stress, which may result in adhesive stress and/or delamination. In particular, thermal stress may be concentrated at particular locations, depending upon the arrangement of the semiconductor dies on the package substrate. Accordingly, various embodiments provide semiconductor packages that include stress-reduction structures configured to reduce the amount of thermal stress applied to the semiconductor packages.

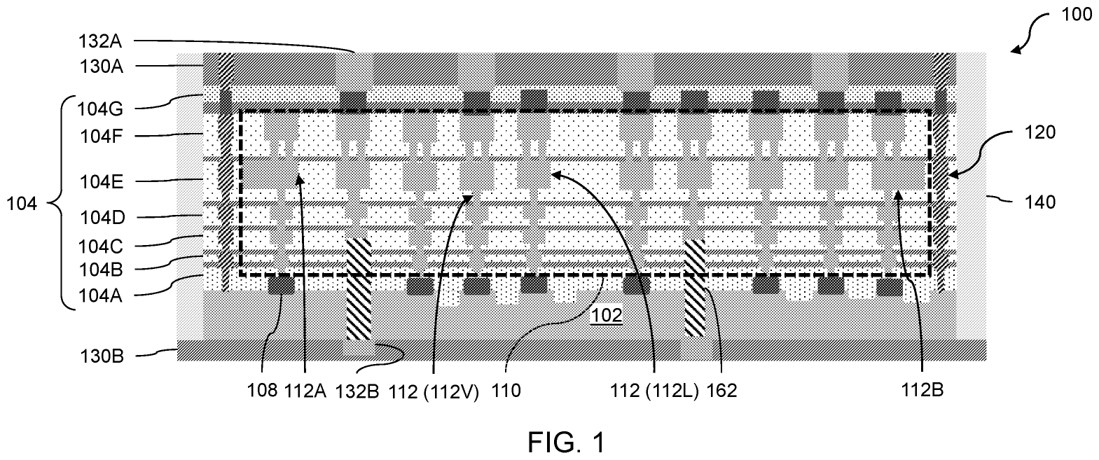

FIG. 1 is a vertical cross-sectional view of a semiconductor die 100, according to various embodiments of the present disclosure. Referring to FIG. 1, the semiconductor die 100 may be, for example, an application-specific integrated circuit (ASIC) chip, an analog chip, a sensor chip, a wireless and radio frequency chip, a voltage regulator chip, a memory chip, or the like. In some embodiments, the semiconductor die 100 may include active components and/or passive components. In some embodiments, the semiconductor die 100 may include a planar semiconductor substrate 102, a dielectric structure 104, an interconnect structure 110 formed within the dielectric structure 104, a seal ring 120, and a through-substrate via (TSV) structure 162.

In some embodiments, the semiconductor substrate 102 may include an elementary semiconductor such as silicon or germanium and/or a compound semiconductor such as silicon germanium, silicon carbide, gallium arsenic, indium arsenide, gallium nitride or indium phosphide. In some embodiments, the semiconductor substrate 102 may be a semiconductor-on-insulator (SOI) substrate. In various embodiments, the semiconductor substrate 102 may take the form of a planar substrate, a substrate with multiple fins, nanowires, or other forms known to people having ordinary skill in the art. Depending on the requirements of design, the semiconductor substrate 102 may be a P-type substrate or an N-type substrate and may have doped regions therein. The doped regions may be configured for an N-type device or a P-type device.

In some embodiments, the semiconductor substrate 102 includes isolation structures defining at least one active area, and a device layer may be disposed on/in the active area. The device layer may include a variety of devices. In some embodiments, the devices may include active components, passive components, or a combination thereof. In some embodiments, the devices may include integrated circuits devices. The devices may be, for example, transistors, capacitors, resistors, diodes, photodiodes, fuse devices, or other similar devices. In some embodiments, the device layer includes a gate structure, source/drain regions, spacers, and the like.

The dielectric structure 104 may be disposed on a front side of the semiconductor substrate 102. In some embodiments, the dielectric structure 104 may include silicon oxide, silicon oxynitride, silicon nitride, a low dielectric constant (low-k) material, or a combination thereof. Other suitable dielectric materials may be within the contemplated scope of disclosure. The dielectric structure 104 may be a single layer or a multiple-layer dielectric structure. For example, as shown in FIG. 1B, the dielectric structure 104 may include multiple dielectric layers 104A-104F, which may include a substrate oxide layer 104A, inter-layer dielectric (ILD) layers 104B-104F, and a passivation layer 104G. However, while FIG. 1 illustrates seven dielectric layers, the various embodiments of the present disclosure are not limited to any particular number of layers.

The dielectric structure 104 may be formed by any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a metalorganic CVD (MOCVD) process, a plasma enhanced CVD (PECVD) process, a sputtering process, laser ablation, or the like.

An interconnect structure 110 may be formed within the dielectric structure 104. The interconnect structure 110 may include metal features 112 disposed in the dielectric structure 104. The metal features 112 may be any of a variety metal lines and via structures that electrically connect the metal lines of adjacent ILD layers 104B-104F. The metal features 112 may include a first connection line 112A that may be used in a die-to-die connection circuit, as discussed in detail below. The metal features 112 may optionally include a second connection line 112B that may be used in a die-to-die connection circuit, as also discussed below.

The interconnect structure 110 may be electrically connected to substrate electrodes 108 disposed on the semiconductor substrate 102, such that the interconnect structure 110 may electrically interconnect semiconductor devices formed on the semiconductor substrate 102. In some embodiments, the substrate electrodes 108 may include metal gates of transistors formed in the device layer of the semiconductor substrate 102.

The interconnect structure 110 may be formed of any suitable electrically conductive material, such as copper (Cu), a copper alloy, aluminum (Al), an aluminum alloy, silver (Ag), combinations thereof, or the like. For example, the interconnect structure 110 may preferably include copper at an atomic percentage greater than 80%, such as greater than 90% and/or greater than 95%, although greater or lesser percentages of copper may be used.

In some embodiments, barrier layers (not shown) may be disposed between the metal features 112 and the dielectric layers of dielectric structure 104, to prevent the material of the metal features 112 from migrating to the semiconductor substrate 102. The barrier layer may include Ta, TaN, Ti, TiN, CoW, or combinations thereof, for example. Other suitable barrier layer materials may be within the contemplated scope of disclosure.

The seal ring 120 may extend around the periphery of the semiconductor die 100. In other words, the seal ring 120 may be disposed adjacent to side surfaces of the semiconductor die 100. For example, the seal ring 120 may be disposed in the dielectric structure 104 and may laterally surround the interconnect structure 110. The seal ring 120 may be configured to protect the interconnect structure 110 from contaminant diffusion and/or physical damage during device processing, such as plasma etching and/or deposition processes.

The seal ring 120 may include copper at an atomic percentage greater than 80%, such as greater than 90% and/or greater than 95% although greater or lesser percentages may be used. The seal ring 120 may include conductive lines and via structures that are connected to each other and may be formed simultaneously with the conductive lines 112L and via structures 112V of the metal features 112 of the interconnect structure 110. The seal ring 120 may be electrically isolated from the metal features 112.

In some embodiments, the metal features 112 and/or the seal ring 120 may be formed by a dual-Damascene process or by multiple single Damascene processes. Single-Damascene processes generally form and fill a single feature with copper per Damascene stage. Dual-Damascene processes generally form and fill two features with copper at once, e.g., a trench and overlapping through-hole may both be filled with a single copper deposition using dual-Damascene processes. In alternative embodiments, the metal features 112 and/or the seal ring 120 may be formed by an electroplating process.

For example, the Damascene processes may include patterning the dielectric structure 104 to form openings, such as trenches and/or though-holes (e.g., via holes). A deposition process may be performed to deposit a conductive metal (e.g., copper) in the openings. A planarization process, such as chemical-mechanical planarization (CMP) may then be performed to remove excess copper (e.g., overburden) that is disposed on top of the dielectric structure 104.

In particular, the patterning, metal deposition, and planarizing processes may be performed for each of the ILD layers 104B-104F, in order to form the interconnect structure 110 and/or the seal ring 120. For example, ILD layer 104B may be deposited and patterned to form openings. A deposition process may then be performed to fill the openings in the ILD layer 104B. A planarization process may then be performed to remove the overburden and form metal features 112 in the ILD layer 104B. These process steps may be repeated to form the ILD layers 104C-104F and the corresponding metal features 112, and thereby complete the interconnect structure 110 and/or seal ring 120.

A front side bonding layer 130A may be disposed over the dielectric structure 104. The front side bonding layer 130A may be formed of a dielectric bonding material. Front side bonding pads 132A may be formed in the front side bonding layer 130A. A backside bonding layer 130B may be formed on the backside of the semiconductor substrate 102. However, in some embodiments, the backside bonding layer 130B may be omitted, depending on the intended location of the semiconductor die 100.

Backside bonding pads 132B may be formed in the backside bonding layer 130B.

The front side bonding layer 130A and the backside bonding layer 130B may be formed by depositing a bonding material using any suitable deposition method. Suitable bonding materials may include silicon oxide or binding polymers as described above, or the like, such as an epoxy, a polyimide (PI), a benzocyclobutene (BCB), and a polybenzoxazole (PBO). Other suitable bonding materials may be within the contemplated scope of disclosure. The front side bonding pads 132A and the backside bonding pads 132B may be electrically conductive features formed of the same materials as the metal features 112. For example, the front side bonding pads 132A and the backside bonding pads 132B may include tungsten (W), copper (Cu), a copper alloy, aluminum (Al), an aluminum alloy, or a combination thereof, or the like.

A dielectric encapsulation (DE) layer 140 may be formed on side surfaces of the semiconductor die 100. The DE layer 140 may be formed of a dielectric material, such as silicon oxide, silicon nitride, a molding compound including a resin and a filler, or the like. The DE layer 140 may be formed by any suitable deposition process, such as spin-coating, lamination, deposition, or the like.

The TSV structure 162 may be disposed in a trench formed in the semiconductor substrate 102. The TSV structure 162 may be electrically connected to the interconnect structure 110 and a backside bonding pad 132B. The TSV structure 162 may be formed of suitable electrically conductive material, such as, copper (Cu), a copper alloy, aluminum (Al), an aluminum alloy, silver (Ag), tungsten (W), combinations thereof, or the like. For example, the TSV structure 162 may preferably include copper at an atomic percentage greater than 80%, such as greater than 90% and/or greater than 95%, although greater or lesser percentages of copper may be used.

In some embodiments, a barrier layer may be disposed between the TSV structures 162 and the semiconductor substrate 102 and the dielectric structure 104. The barrier layer may include Ta, TaN, Ti, TiN, CoW, or combinations thereof, for example. Other suitable barrier layer materials may be within the contemplated scope of disclosure.

### Semiconductor Package Including Stress-Reduction Chamfers

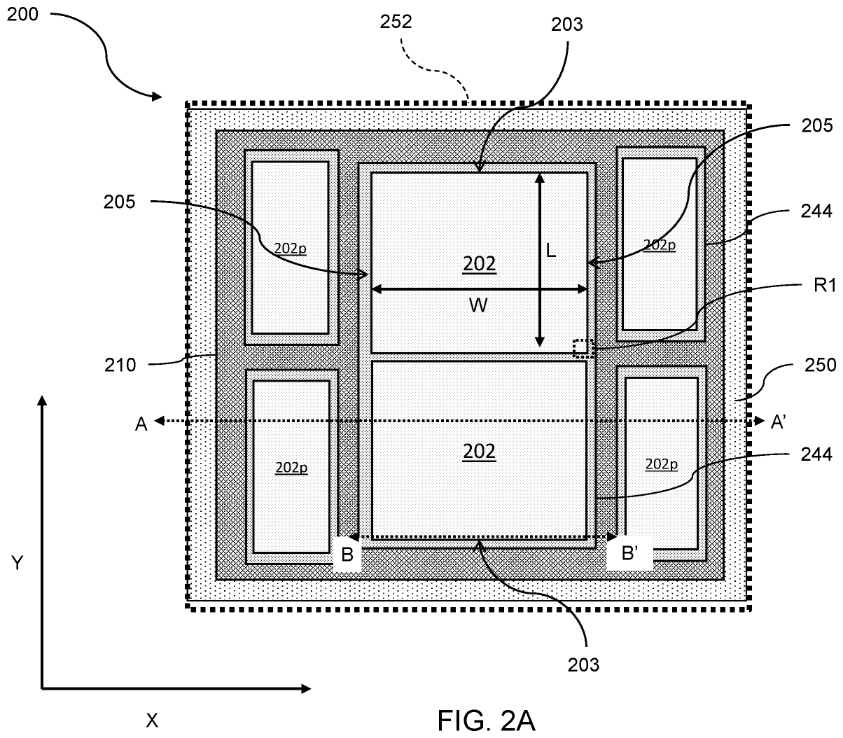

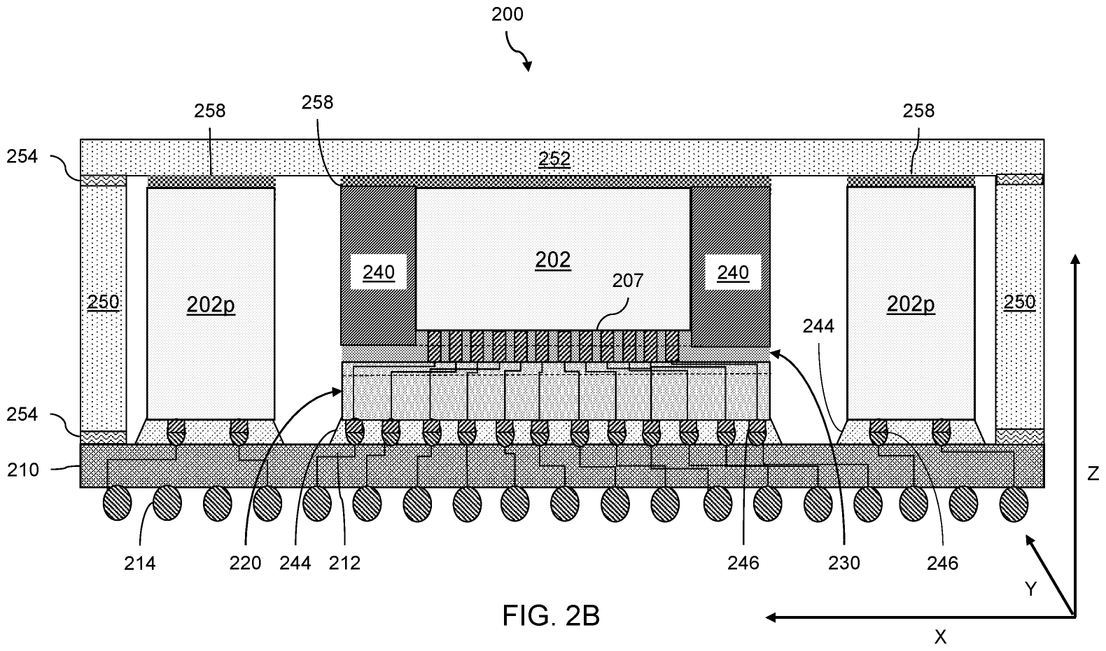

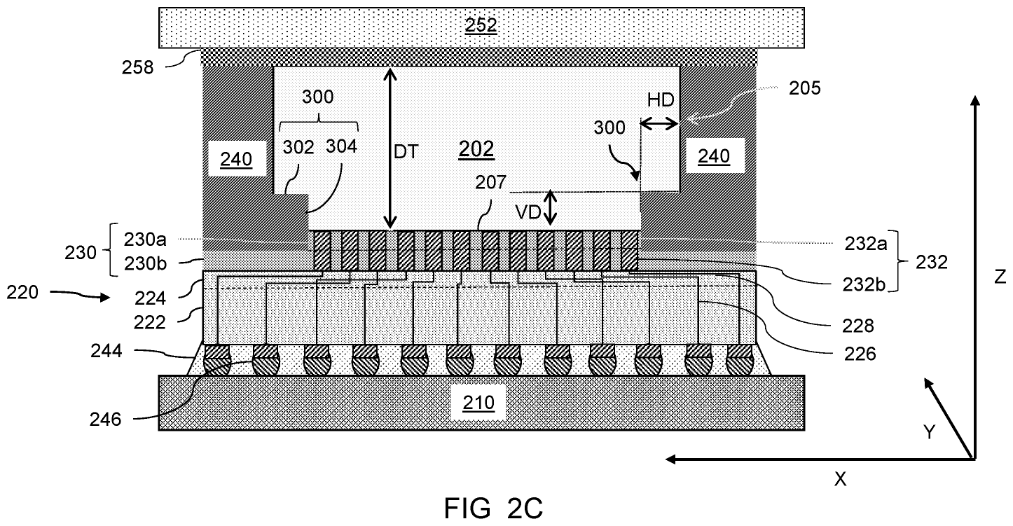

FIG. 2A is a simplified top view of a semiconductor package 200, according to various embodiments of the present disclosure. FIG. 2B is a vertical cross-sectional view taken along line A-A′ of FIG. 2A. FIG. 2C is a vertical cross-sectional view taken along line B-B′ of FIG. 2A.

Referring to FIGS. 1, 2A, 2B, and 2C, the semiconductor package 200 may include a package substrate 210, an interposer 220 disposed on the package substrate 210, one or more semiconductor dies 202 (e.g., semiconductor die 100 described above in FIG. 1) disposed on the interposer 220, a package ring 250 disposed on the perimeter of the package substrate 210, a cover 252 disposed on the package ring 250, a ring adhesive 254 bonding the package ring 250 to the package substrate 210 and/or to the cover 252, and a thermal interface material 258 bonding the semiconductor dies 202 to the cover 252.

The package substrate 210 may be any suitable package substrate, such as a polymer substrate, organic resin substrate, a laminate substrate, a printed circuit board, or the like. Common laminate substrates include fiberglass-reinforced epoxy-laminated sheets (FR4) substrates and bismaleimide-triazine (BT) substrates. The package substrate 210 may include metal package traces 212 that are electrically connected to corresponding package balls 214 (e.g., soldier balls).

In various embodiments, the semiconductor dies 202 may each include a semiconductor die 100, as shown in FIG. 1. In some embodiments, the semiconductor package 200 may include multiple vertically stacked and interconnected semiconductor dies 202. The semiconductor dies 202 may be any suitable type of semiconductor device or chip, depending on the intended function of the semiconductor package 200. For example, the semiconductor dies 202 may include system-on-chip (SoC) dies, flip chips (FC), three-dimensional integrated circuits (3DICs), wafer level packages (WLPs), package on package (POP), system on integrated circuit (SoIC) devices, application specific integrated circuit (ASIC) devices, or the like.

In some embodiments, the semiconductor dies 202 may include logic devices and memory devices, such as high bandwidth memory (HBM) devices, dynamic random access memory (DRAM) devices, or the like. In some embodiments, the semiconductor package 200 may include peripheral semiconductor dies 202p arranged around the semiconductor dies 202. The peripheral semiconductor dies 202p may electrically connected to the package substrate 210 without an interposer 220. In some embodiments, the semiconductor dies 202 may include SoC and/or ASIC devices, and the peripheral semiconductor dies 202p may include, for example, logic devices and memory devices, such as high bandwidth memory (HBM) devices, dynamic random access memory (DRAM) devices, or the like. However, the present disclosure is not limited to any particular types of semiconductor dies 202 and peripheral semiconductor dies 202p.

The semiconductor dies 202 may include opposing first side walls 203 that extend in an X direction and opposing second sidewalls 205 that extend in a Y direction. The X and Y directions may be perpendicular to one another and may both be horizontal directions (e.g., disposed in a horizontal plane). Thicknesses DT of the semiconductor dies 202 may be measured vertically in a Z direction that is perpendicular to the horizontal X and Y directions. For example, as shown in FIG. 2C, the thickness DT of the semiconductor dies 202 may be measured in the vertical Z direction. The semiconductor dies 202 may each have a length L measured in a first horizontal direction (e.g., the X direction) and a width W measured in a second horizontal direction (e.g., the Y direction). In some embodiments, the length L and the width W may be the same. In other embodiments, the width W may be greater than the length L, or the length L may be greater than the width W.

The interposer 220 may be configured to electrically connect the semiconductor dies 202 to the package substrate 210. For example, the interposer 220 may be a silicon interposer, a redistribution layer (RDL) interposer, a chip-on-wafer-on-substrate (CoWoS) interposer (which may comprise silicon), or the like. CoWoS interposers may include chip-on-wafer-on-substrate redistribution layer (CoWoS-R) interposers and chip-on-wafer-on-substrate local silicon interconnect bridge (CoWoS-L) interposers, for example.

The package ring 250 may extend around the perimeter of the package substrate 210, so as to surround the interposer 220 and the semiconductor dies 202. The package ring 250 may be formed of a first metal or metal alloy, such as stainless steel (e.g., SUS304 or SUS440).

The cover 252, which may also be referred to as a lid, may be formed of a second metal or metal alloy having high thermal conductivity, such as copper, gallium, titanium, alloys thereof, or the like. The cover 252 may have a thickness T1 ranging from 50 μm to 3500 μm, such as from 100 μm to 3000 μm, although greater or lesser thicknesses may be used.

The thermal interface material 258 may be formed of any suitable adhesive material having a high thermal conductivity. For example, the thermal interface material 258 may be a thermal paste, a thermal adhesive, a thermal gap filler, a thermally conductive pad, thermal tape, a metal thermal interface material, or the like. The thermal interface material 258 and/or the ring adhesive 254 may be applied in layers have a thickness T3 ranging from 20 μm to 250 μm, such as from 30 μm to 200 μm, although greater or lesser thicknesses may be used.

In various embodiments, the semiconductor dies 202 may be laterally surrounded by a molding layer 240 (e.g., a dielectric encapsulation layer). The molding layer 240 may be formed of a dielectric material, such as molding compound including a resin and a filler, or the like. The molding layer 240 may be formed by any suitable deposition process, such as spin-coating, lamination, deposition, or the like. After deposition, the molding layer 240 may be cured using heat and/or light.

The interposer 220 and the peripheral semiconductor dies 202p may be electrically connected to the package substrate 210 by substrate bonding structures 246. An underfill material 244, such as a resin or the like, may be disposed under the interposer 220 and the peripheral semiconductor dies 202p, surrounding the substrate bonding structures 246. In some embodiments, the substrate bonding structures 246 may include bonding pads and solder balls or micro bumps.

The semiconductor dies 202 may be attached to the interposer 220 by a bonding layer 230 and bonding pad structures 232. The bonding layer 230 may include a dielectric material such as silicon oxide or the like. The pad structures 232 may include a metal such as copper or the like and may be configured to electrically connect the semiconductor dies 202 to the interposer 220.

The bonding layer 230 may be formed by bonding a first bonding layer 230a formed on the semiconductor dies 202 and a second bonding layer 230b formed on the interposer 220. First bonding pads 232a may be disposed in first bonding layer 230a and second bonding pads 232b may be disposed in the second bonding layer 230b. In various embodiments, a hybrid fusion bonding process may be performed to bond the first and second bonding layers 230a, 230b and form the bonding layer 230, and to fuse the first and second bonding pads 232a, 232b and form the pad structures 232. In some embodiments, the first and second bonding layers 232a, 232b may be formed of silicon oxide and the first and second bonding pads 232a, 232b may be formed of copper or a copper alloy, for example.

In various embodiments, the interposer 220 may include a silicon substrate 222 and at least one redistribution layer 224 disposed thereon. The silicon substrate 222 may include metal via structures 226 that are electrically connected to the substrate bonding structures 246. The redistribution layer 224 may include conductive metal features 228 configured to electrically connect the pad structures 232 to the via structures 226.

Stress may accumulate in certain areas of the semiconductor package 200. For example, due to coefficient of thermal expansion (CTE) differences between the interposer 220, the bonding layer 230, and/or the semiconductor dies 202, thermal stress may accumulate. For example, thermal stress may be concentrated at corners of the semiconductor dies 202 and underlying portions of the interposer 220 and/or may accumulate below adjacent portions of the molding layer 240.

As shown in FIG. 2C, chamfers 300 may be formed at the corners of the semiconductor dies 202. In particular, the chamfers 300 may be formed by removing at least a lower portion of one or more corners of the semiconductor dies 202, including corresponding corner portions of a bottom surface 207 of the semiconductor dies 202. In other words, the chamfers 300 may be recesses formed in the corners of a bottom surface 207 of the semiconductor dies 202, including corner portions of adjacent first and second side walls 203, 205 of each semiconductor die 202. The chamfers 300 may be formed using any suitable method, such as by using a die saw or the like to cut at least portions of the corners of the semiconductor dies 202. For example, in some embodiments, the chamfers 300 may be formed by cutting at least corners of semiconductor substrates of the semiconductor dies 202.

In some embodiments, the chamfers 300 may include a side surface 304 and an upper surface 302. The upper surface 302 may face the interposer 220 and may be horizontally aligned. The side surface 304 may extend from the upper surface 302 to the bottom surface 207 of the semiconductor die 202. The molding layer 240 may be disposed in the chamfers 300. For example, the chamfers 300 may be filled with the molding material of the molding layer 240, after the semiconductor dies 202 are bonded to the interposer 220.

The chamfers 300 may have a vertical depth VD measured in a first vertical direction (e.g., the Z direction) and a horizontal depth HD. In various embodiments, the vertical depth VD may be greater than zero and less than or equal to the die thickness DT. For example, the vertical depth VD may range from 0.5% to 75%, such as from 1% to 50%, or from 10% to 25% of the die thickness DT. In some embodiments, the vertical depth VD may be limited to 50% or less, such as 25% or less of the die thickness DT, in order to reduce an amount of stress applied to the bonding layer 230 by the molding layer 240.

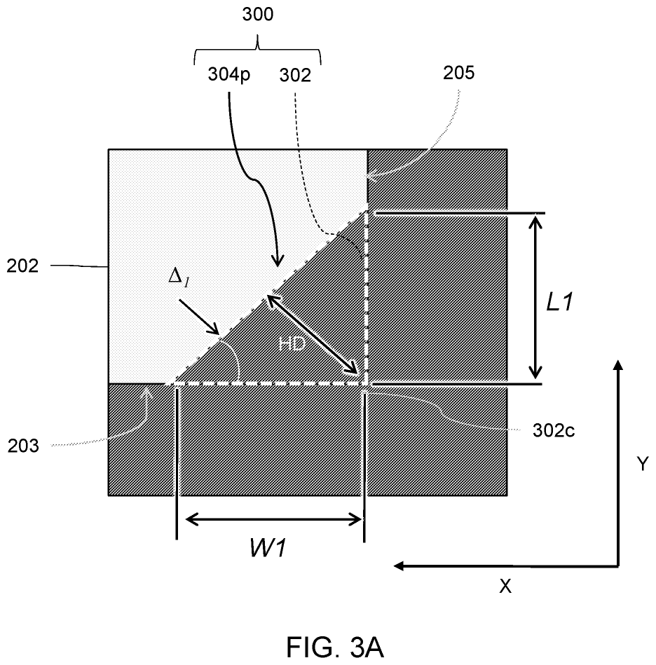

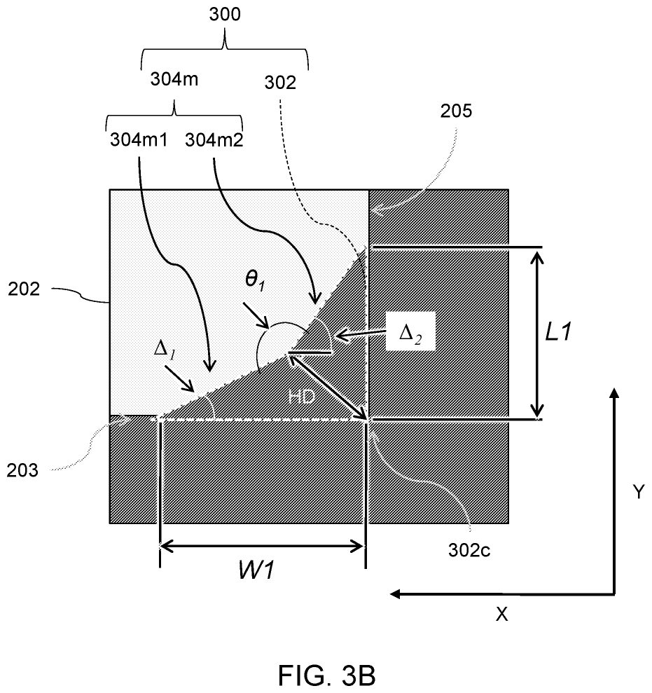

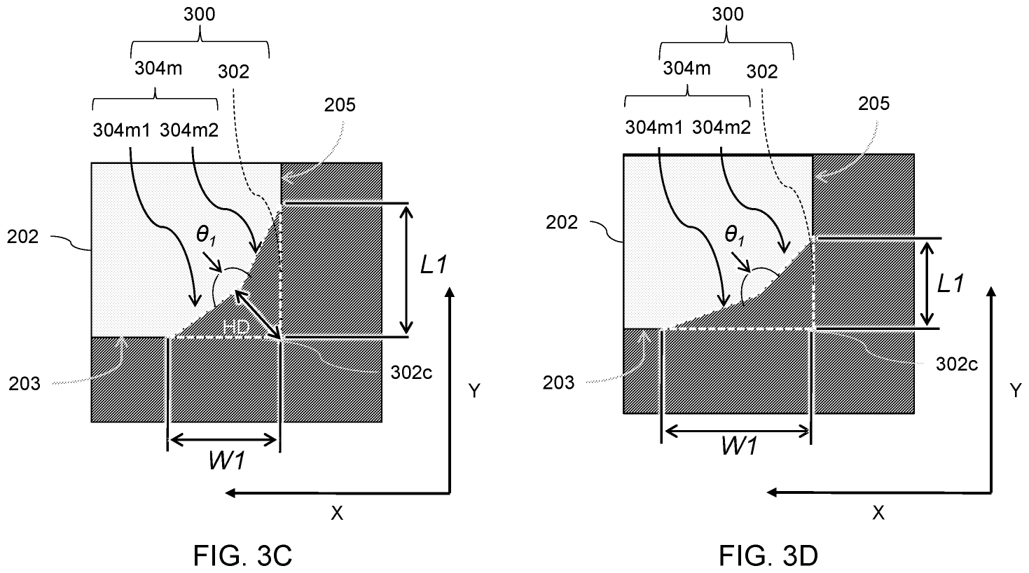

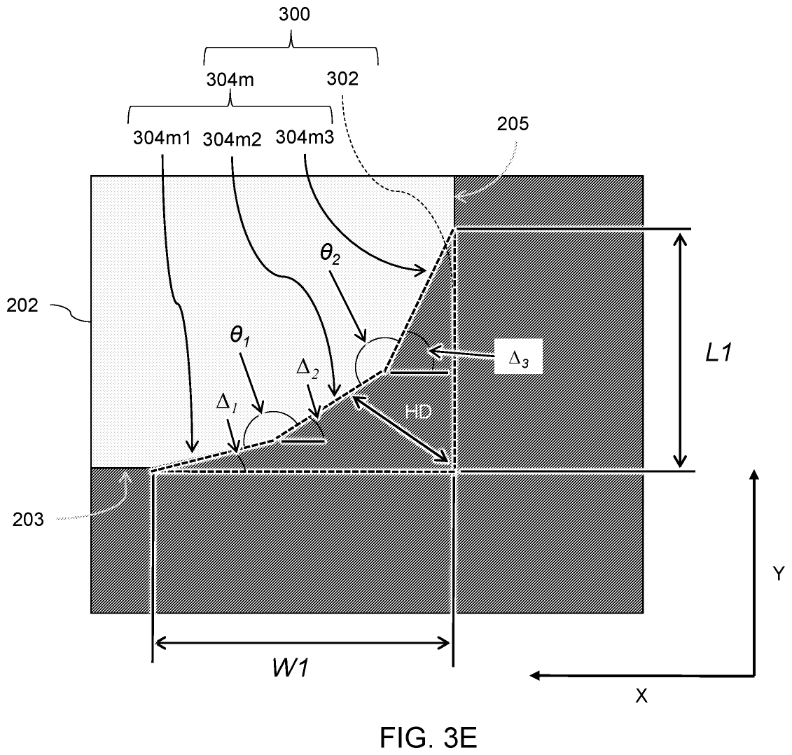

As discussed in detail below with regard to FIGS. 3A-3D, the chamfer horizontal depth HD may represent a horizontal thickness of the semiconductor die 202 taken from an uncut corner of the semiconductor die 202 above the chamfer 300 to the closest vertical sidewall of the chamfer 300. In various embodiments, the horizontal depth HD may be greater than zero and less than 7500 μm, such as from 1 μm to 6000 μm, or from 100 μm to 5000 μm. In some embodiments, the horizontal depth may preferably range from greater than zero to 1000 μm, such as from about 1 μm to 1000 μm, in order to reduce die stress while minimizing volume reduction of the semiconductor die 202.

FIGS. 3A-3E are partially transparent enlarged top views of a chamfered region R1 of a semiconductor die 202 of FIG. 2A, showing different configurations (e.g., shapes) that may be included in chamfers of FIG. 2C, according to various embodiments of the present disclosure. The embodiments of FIGS. 3A-3E may include similar features. As such, the description of such features may not be repeated.

Referring to FIG. 3A, the chamfer 300 may include chamfered surfaces. The chamfered surfaces may include a planar side surface 304p and a planar upper surface 302 (represented by dashed lines). The side surface 304p may define substantially vertical plane (e.g., the side surface 304p may be disposed entirely within a vertical plane that extends parallel to the Z direction of FIG. 2B). The upper surface 302 may define a substantially horizontal plane (e.g., the upper surface 302 may be entirely disposed in a plane that extends parallel to the X and Y directions). A horizontal depth HD of the chamfer 300 may be measured between a perpendicular corner 302c of the upper surface 302 (e.g., a corner of the upper surface that is at least partially defined by adjacent first and second side walls 203, 205 of the semiconductor die 202) the bottom a corner formed by an intersection of adjacent the first and second sidewalls 203, 205 of the semiconductor die 202) and the planar side surface 304p. In other words, the horizontal depth HD may represent a minimum distance between the corner 302c and the planar side surface 304p.

The chamfer 300 may have a width W1 taken in the first horizontal direction (e.g., the X direction) and a length L1 taken in the second horizontal direction (e.g., the Y direction). The width W1 and the length L1 may be substantially the same (e.g., within +/−5%). As such, an exterior angle Δ1 formed between the planar side surface 304p and the X direction may range from 30° to 60°, such as from 40° to 50°, or may be about 45°. In some embodiments, the width W1 and the length L1 may be less than 50% of the width W and the length L of the semiconductor die 202 (see FIG. 2A). For example, the width W1 range from 0.5% to 50%, such as from 1% to 24%, or from 1.5% to 10% of the width W of the semiconductor die 202, and the length L1 may range from 0.5% to 50%, such as from 1% to 24%, or from 1.5% to 10% of the length L of the semiconductor die 202. In some embodiments, the width W1 and the length L1 may preferably be 5% or less than of the width W and the length L of the semiconductor die 202, in order to reduce die stress while minimizing volume reduction of the semiconductor die 202. For example, the width W1 may range from 0.5% to 5% of the width W and the length L1 may range from 0.5% to 5% of the length L.

Referring to FIG. 3B, the chamfer 300 may include a multiplanar side surface 304m and a planar upper surface 302 (represented by dashed lines). In particular, the multiplanar side surface 304m may include a first side surface 304m1 that defines a first vertically aligned plane and a second side surface 304m2 that defines a second vertically aligned plane.

Herein, an “interior angle” may be an angle formed inside of a semiconductor die 202, and an “exterior angle: may be an angle formed outside of a semiconductor die 202. An interior angle θ₁ formed between the first side surface 304m1 and the second side surface 304m2, may range from 179° to 100°, such as from 150° to 175°. An exterior angle Δ₁ formed between the first side surface 304m1 and the X direction, and an exterior angle Δ₂ formed between the second side surface 304m2 and the X direction, may each be less than 90°. In some embodiments, a sum of exterior angles Δ₁ and Δ₃, may be less than 90°. In some embodiments, angle 41 may be smaller than angle Δ₂. Accordingly, the multiplanar side surface 304m may increase stress reduction, as compared to the planar side surface 304p of FIG. 3A.

The width W1 and the length L1 of the chamfer 300 may be substantially the same. In some embodiments, the width W1 and the length L1 may be less than 50% of the width W and the length L of the semiconductor die 202 (see FIG. 2A). For example, the width W1 and the length L1 may range from 0.5% to 50%, such as from 1% to 24%, or from 1.5% to 10% of the corresponding width W and the length L of the semiconductor die 202. The first side surface 304m1 and the second side surface 304m2 may have substantially the same area (e.g., with +/−5%). In some embodiments, the horizontal distance HD may be measured between the corner 302c of the upper surface 302 and the closest portion of the multiplanar side surface 304m. In some embodiments, the horizontal distance HD may be measured between the corner 302c and an intersection of the first side surface 304m1 and the second side surface 304m2.

Referring to FIG. 3C, the chamfer 300 may include a multiplanar side surface 304m and a planar upper surface 302 (represented by dashed lines). In particular, the multiplanar side surface 304m may include a first side surface 304m1 that defines a first vertically aligned plane and a second side surface 304m2 that defines a second vertically aligned plane. An interior angle θ₁ formed between the first side surface 304m1 and the second side surface 304m2 may range from about 179° to about 100°, such as from about 150° to about 175°.

The width W1 and the length L1 of the chamfer 300 may be different. For example, the length L1 may be greater than the width W1. As such, the first side surface 304m1 may have a smaller area than the second side surface 304m2, in some embodiments.

Referring to FIG. 3D, the chamfer 300 may include a multiplanar side surface 304m and a planar upper surface 302 (represented by dashed lines). In particular, the multiplanar side surface 304m may include a first side surface 304m1 that defines a first vertically aligned plane and a second side surface 304m2 that defines a second vertically aligned plane. An interior angle θ₁ formed between the first side surface 304m1 and the second side surface 304m2 may range from about 179° to about 100°, such as from about 150° to about 175°.

The chamfer 300 may have a width W1 taken in the X direction and a length L1 taken in the Y direction. The width W1 and the length L1 may be different. For example, the length L1 may be less than the width W1. As such, the first side surface 304m1 may have a larger area than the second side surface 304m2, in some embodiments.

Referring to FIG. 3E, the chamfer 300 may include a multiplanar side surface 304m and a planar upper surface 302 (represented by dashed lines). In particular, the multiplanar side surface 304m may include a first side surface 304m1 that defines a first vertically aligned plane, a second side surface 304m2 that defines a second vertically aligned plane, and a third side surface 304m3 that defines a third vertically aligned plane. The first side surface 304m1, the second side surface 304m2, and the third side surface 304m3 may be angled with respect to one another.

For example, an interior angle θ₁ formed between the first side surface 304m1 and the second side surface 304m2, and an interior angle θ₂ formed between the second side surface 304m2 and the third side surface 304m3 may each be less than 180° and greater than 90°. For example, angle θ₂ and angle θ3 may each range from 179° to 100°, such as from 175° to 125°, or 170° to 130°. An exterior angle Δ1 formed between the first side surface 304m1 and the X direction, an exterior angle Δ₂ formed between the second side surface 304m2 and the X direction, and an exterior angle Δ₃ formed between the third side surface 304m3 and the X direction may each be less than 90°. In some embodiments, a sum of exterior angles Δ₁, Δ₂, and Δ₃, may be less than 90°.

Accordingly, the three plane multiplanar side surface 304m of FIG. 3E may increase stress reduction, as compared to the two plane multiplanar side surface 304m of FIG. 3B. In other embodiments, the chamfer 300 may include a multiplanar side surface having more than three planar surfaces, such as from 4 to 10 or more planar surfaces.

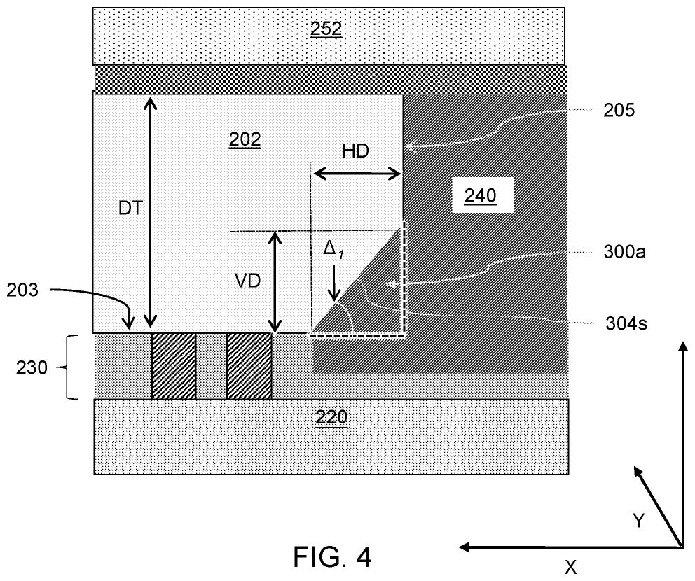

FIG. 4 is a vertical cross-sectional view of an alternative chamfer 300a that may be included in the semiconductor dies 202 of FIGS. 2A-2C, according to various embodiments of the present disclosure. Referring to FIG. 4, the chamfer 300a may include a sloped side surface 304s and may omit a top surface. In particular, the sloped side surface 304s may be sloped with respect to the vertical Z direction. For example, in some embodiments the slope of the sloped side surface 304s may range from 30° to 60°, such as from 40° to 50°, or may be about 45°, with respect to the Z direction. Accordingly, the horizontal depth HD and the vertical depth VD of the chamfer 300 may be the same or may be different, depending on the slop of the sloped side surface 304s.

The sloped side surface 304s may extend between adjacent first and second side walls 203, 205 (see FIG. 2A) of the semiconductor die 202. The sloped side surface 304s may be planar, as shown in FIG. 3A. As such, the chamfer 300a may be formed by making a single cut using an angled die saw. In the alternative, the sloped side surface 304s may be multiplanar as shown in FIGS. 3B-3E. In such embodiments, the sloped side surface 304s may be formed by multiple cuts with an angled die saw.

In various embodiments, the horizontal depth HD and the vertical depth VD of the chamfer 300a may be the same or different. An exterior angle Δ1 formed between the planar side surface 304p and the X direction may range from 30° to 60°, such as from 40° to 50°, or may be about 45°, depending upon the relative dimensions of the horizontal depth HD and the vertical depth VD.

According to various embodiments, the chamfer 300a may be configured to reduce the accumulation of stress below corners of the semiconductor die 202, which may be due to CTE differences between the interposer 220, the semiconductor die 202, and/or the molding layer 240. In particular, the chamfer 300a may reduce thermal stress accumulation in the interposer 220, adjacent to corners of the semiconductor dies 202.

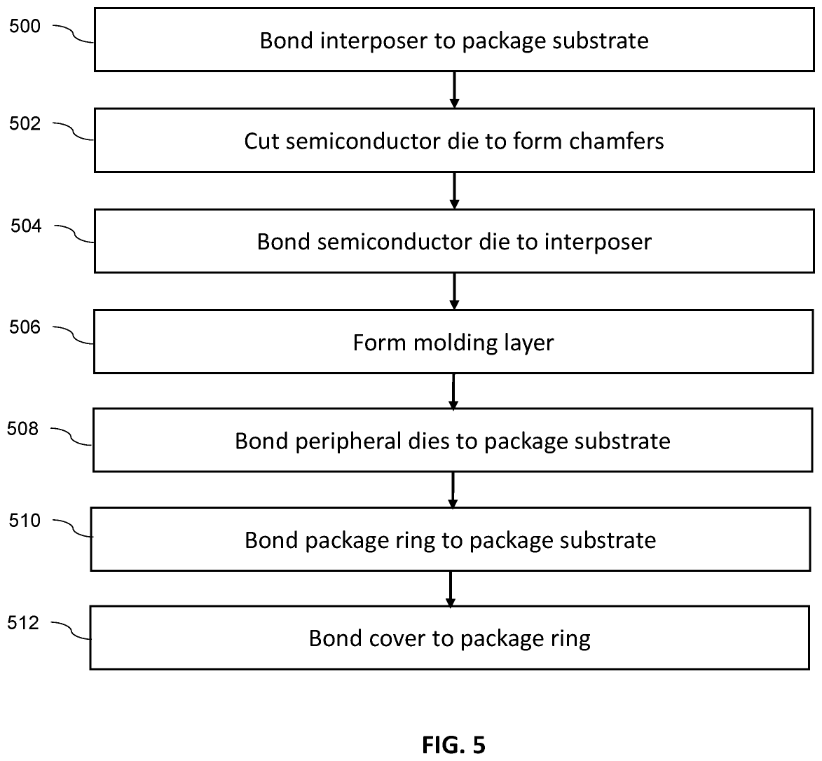

FIG. 5 is a flow diagram showing a method of forming a package substrate, according to various embodiments of the present disclosure. Referring to FIGS. 2A, 2B, and 5, in step 500, the method may include bonding an interposer 220 to a package substrate 210.

In step 502, a semiconductor die 202 may be cut to form chamfers 300 at corners of a bottom surface of the semiconductor die 202. For example, the semiconductor die 202 may be cut using a die saw to form chamfers 300 as shown in FIGS. 3A-4.

In step 504, the bottom surface of the semiconductor die 202 may be bonded to the interposer 220. For example, the bonding may include using a hybrid fusion bonding process.

In step 506, a molding layer 240 may be formed around the semiconductor die 202. In step 508, peripheral dies 202P may be optionally bonded to the package substrate 210.

In step 510, a package ring 250 may be bonded to the package substrate 210. The package ring 250 may surround the semiconductor die 202 and the peripheral dies 202P. In step 512, a cover 252 may be bonded to the package ring 250. In some embodiments, a thermal interface material 258 may be used to bond the semiconductor die 202 to the cover 252.

In some embodiments, step 504 may include cutting multiple semiconductor dies 202 to form chamfers 300, and step 504 may include bonding the semiconductor dies 202 to the interposer 220.

Various embodiments provide a semiconductor package 200 that may include: a package substrate 210 comprising a horizontal top surface; an interposer 220 bonded to the top surface of the package substrate 210; a semiconductor die 202 bonded to the interposer 220, the semiconductor die 202 comprising a bottom surface 207 that faces a top surface of the interposer 220 and chamfers 300 formed in corners of the bottom surface of the semiconductor die 202, wherein the chamfers 300 include chamfered surfaces (e.g., 302, 304, 304m1, 304m2); and a molding layer 240 surrounding the semiconductor die 202 and contacting the chamfered surfaces (e.g., 302, 304, 304m1, 304m2).

In some embodiments, the chamfered surfaces comprise an upper surface 302 that faces the interposer 220 and a side surface 304 that extends from the upper surface 302 to the bottom surface 207 of the semiconductor die 202. In some embodiments, the side surface 304 extends between adjoining first and second sidewalls of the semiconductor die 202. In various embodiments, the side surface 304 defines a single vertically aligned plane.

In various embodiments, the chamfer 300 may comprises a multiplanar side surface 304m that comprises a first side surface 304m1 that defines a first vertically aligned plane, a second side surface 304m2 that defines a second vertically aligned plane, and a third side surface 304m3 that defines a third vertically aligned plane. An internal angle formed between the first side surface 304m1 and the second side surface 304m2 may range from 179° to 100°. An internal angle formed between the second side surface 304m2 and the third side surface 304m3 may range from 179° to 100°. An area of the first side surface 304m1 may be greater than an area of the second side surface 304m2.

In various embodiments, a vertical depth VD of each chamfer 300 ranges from 0.5% to 75% of a thickness DT of the semiconductor die 202. In some embodiments, the vertical depth VD may preferably be 20% or less than the thickness DT, such as from 0.5% to 20% of the thickness DT, in order to reduce die stress while minimizing volume reduction of the semiconductor die 202. A minimum horizontal distance HD between a perpendicular corner 302c of the upper surface 302 and the side surface 304 may be less than 5000 microns (μm). In various embodiments, each chamfer 300 comprises a sloped side surface 304s that extends from adjacent first and second sidewalls 203, 205 of the semiconductor die to the bottom surface of the semiconductor die, the sloped side surface having a slope ranging from 30° to 60° in order to reduce die stress while minimizing volume reduction of the semiconductor die 202.

In some embodiments, the semiconductor package 200 may further comprise: peripheral dies 202p disposed around the semiconductor die 202 and bonded to the package substrate 210; a package ring 250 disposed on a perimeter of the package substrate 210 surrounding the semiconductor die 202 and the peripheral semiconductor dies 202p; and a cover 252 disposed on the package ring 250.

According to various embodiments, provided is a semiconductor package 200 comprising: a package substrate 210 comprising a horizontal top surface; an interposer 220 bonded to the top surface of the package substrate 210; a semiconductor die 202 disposed on the interposer, the semiconductor die comprising a bottom surface 207 that faces a top surface of the interposer 220 and chamfers 300 formed in corners of the bottom surface 207 of the semiconductor die 202, wherein the chamfers 300 include chamfered surfaces (e.g., 302, 304, 304m1, 304m2); a bonding layer 230 bonding the semiconductor die to the interposer; and a molding layer disposed on the bonding layer and surrounding the semiconductor die, the molding layer 240 extending between the semiconductor die 202 and the interposer 220 and contacting the chamfered surfaces.

According to various embodiments, provided is a semiconductor package 200 comprising: a package substrate 210 comprising a horizontal top surface; an interposer 220 bonded to the top surface of the package substrate 210; a first semiconductor die 202 bonded to a top surface of the interposer 220; a second semiconductor die 202 bonded to the top surface of the interposer 220 adjacent to the first semiconductor die 202; and a molding layer 240 surrounding the first semiconductor die 202 and the second semiconductor die 202; peripheral dies 202p bonded to the package substrate 210 adjacent to the interposer 220. The first and second semiconductor dies 202 each comprise: a bottom surface that faces the top surface of the interposer; and chamfers 300 formed in corners of the bottom surface 207, wherein the chamfers 300 include chamfered surfaces and the molding layer 240 contacts the chamfered surfaces.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a package substrate comprising a top surface that extends in a horizontal direction;
an interposer bonded to the top surface of the package substrate;
a semiconductor die bonded to a top surface of the interposer, the semiconductor die comprising:
a bottom surface that faces the top surface of the interposer; and
chamfers formed in corners of the bottom surface of the semiconductor die, wherein the chamfers include chamfered surfaces; and
a molding layer surrounding the semiconductor die and contacting the chamfered surfaces.

2. The semiconductor package of claim 1, wherein the chamfered surfaces comprise:
an upper surface that faces the interposer; and
a side surface that extends from the upper surface to the bottom surface of the semiconductor die.

3. The semiconductor package of claim 2, wherein the side surface extends between adjoining first and second sidewalls of the semiconductor die.

4. The semiconductor package of claim 3, wherein the side surface defines a single vertically aligned plane.

5. The semiconductor package of claim 3, wherein:
the side surface comprises:
a first side surface that defines a first vertically aligned plane; and
a second side surface that defines a second vertically aligned plane; and
an internal angle formed between the first side surface and the second side surface ranges from 179° to 100°.

6. The semiconductor package of claim 5, wherein an area of the first side surface is greater than an area of the second side surface.

7. The semiconductor package of claim 5, wherein an area of the first side surface is equal to an area of the second side surface.

8. The semiconductor package of claim 3, wherein the side surface comprises:
a first side surface that defines a first vertically aligned plane;
a second side surface that defines a second vertically aligned plane; and
a third side surface that defines a third vertically aligned plane,
wherein an internal angle formed between the first side surface and the second side surface ranges from 179° to 100°, and
wherein an internal angle formed between the second side surface and the third side surface ranges from 179° to 100°.

9. The semiconductor package of claim 2, wherein a vertical depth of each chamfer ranges from 0.5% to 75% of a thickness of the semiconductor die.

10. The semiconductor package of claim 2, wherein a minimum horizontal distance between a perpendicular corner of the upper surface and the side surface is less than 5000 microns (μm).

11. The semiconductor package of claim 10, wherein the minimum horizontal distance ranges from 100 μm to 5000 μm.

12. The semiconductor package of claim 1, wherein each chamfer comprises a sloped side surface that extends from adjacent first and second sidewalls of the semiconductor die to the bottom surface of the semiconductor die, the sloped side surface having a slope ranging from 30° to 60°.

13. The semiconductor package of claim 1, further comprising:
peripheral dies disposed around the semiconductor die and bonded to the package substrate;
a package ring disposed on a perimeter of the package substrate surrounding the semiconductor die and the peripheral semiconductor dies; and
a cover disposed on the package ring.

14. A semiconductor package comprising:
a package substrate comprising a top surface that extends in a horizontal direction;
an interposer bonded to the top surface of the package substrate;
a semiconductor die disposed on the interposer, the semiconductor die comprising:
a bottom surface that faces a top surface of the interposer; and
chamfers formed in corners of the bottom surface of the semiconductor die;
a bonding layer bonding the semiconductor die to the interposer; and
a molding layer disposed on the bonding layer and surrounding the semiconductor die, the molding layer extending between the semiconductor die and the interposer and contacting the chamfers.

15. The semiconductor package of claim 14, wherein:
the semiconductor die has a semiconductor die width, a semiconductor die length, and a semiconductor die thickness;
a vertical depth of each chamfer ranges from 0.5% to 75% of the semiconductor die thickness;
a length of each chamfer ranges from 0.5% to 50% of the semiconductor die length; and
a width of each chamfer ranges from 0.5% to 50% of the semiconductor die width.

16. The semiconductor package of claim 15, wherein:
vertical depth of each chamfer ranges from 0.5% to 20% of the semiconductor die thickness;
the length of each chamfer ranges from 0.5% to 5% of the semiconductor die length; and
the width of each chamfer ranges from 0.5% to 5% of the semiconductor die width.

17. The semiconductor package of claim 14, wherein each chamfer comprises:
an upper surface that faces the interposer; and
a side surface that extends from the upper surface to the bottom surface of the semiconductor die,
wherein the side surface comprises:
a first side surface that defines a first vertically aligned plane; and
a second side surface that defines a second vertically aligned plane,
wherein an internal angle formed between the first side surface and the second side surface ranges from 179° to 100°.

18. A method of forming a semiconductor package, comprising:
bonding an interposer to a top surface of the package substrate;
cutting a semiconductor die to form chamfers at corners of a bottom surface of the semiconductor die;
bonding the bottom surface of the semiconductor die to a top surface of the interposer; and
forming a molding layer that surrounds the semiconductor die and contacts the chamfers.

19. The method of claim 18, wherein the cutting of the semiconductor die comprises using a die saw to cut the corners such that each chamfer comprises:
an upper surface that faces the interposer; and
a side surface that extends from the upper surface to the bottom surface of the semiconductor die.

20. The method of claim 18, further comprising:
bonding peripheral dies to the package substrate on opposing sides of the semiconductor die;
bonding a package ring disposed to a perimeter of the package substrate; and
bonding a cover to the package ring,
wherein the semiconductor die is hybrid fusion bonded to the package substrate.
